(19) United States
(12) Patent Application Publication
(10) Pub. No.: US 2025/0185253 A1
(43) Pub. Date: Jun. 5, 2025

(54) METHODS OF FORMING FERROELECTRIC DEVICES

(71) Applicant: Tokyo Electron Limited, Tokyo (JP)

(72) Inventors: Kandabara Tapily, Albany, NY (US); Dina H. Triyoso, Albany, NY (US); Robert D. Clark, Leuven (BE)

(21) Appl. No.: 18/902,434

(22) Filed: Sep. 30, 2024

Related U.S. Application Data
(60) Provisional application No. 63/605,020, filed on Dec. 1, 2023.

(51) Int. Cl. H10B 53/30

(52) U.S. Cl. CPC H10B 53/30

(57) ABSTRACT

A method of forming a ferroelectric device includes forming a first electrode material layer over a substrate; forming a ferroelectric material layer over the first electrode material layer; forming a first non-ferroelectric material layer over the ferroelectric material layer; and forming a second electrode material layer over the first non-ferroelectric material layer, the second electrode material layer including tungsten, the ferroelectric device being formed by a stack including the first electrode material layer, the ferroelectric material layer, the first non-ferroelectric material layer, and the second electrode material layer.

### CROSS-REFERENCE TO RELATED APPLICATIONS

This application claims the benefit of U.S. Provisional Application No. 63/605,020 filed on Dec. 1, 2023, titled “Method of Forming a Ferroelectric Device Containing an Oxide Interlayer,” which application is hereby incorporated herein by reference.

### TECHNICAL FIELD

The present invention relates generally to electronic devices, and, in particular embodiments, to electronic devices incorporating ferroelectric materials and methods for manufacturing the same.

### BACKGROUND

Unlike conventional dielectrics, ferroelectric materials possess a characteristic net electrical polarization—the remanent polarization, Pᵣ—even in the absence of an electric field E. When a sufficiently strong field is applied in opposition to Pᵣ, the polarization state of the ferroelectric switches, and the ferroelectric retains polarization−Pᵣ once the field is removed. As a result, ferroelectric materials provide a physical implementation of a bit (two distinct polarization states) that does not require refreshing.

Because ferroelectrics typically have high dielectric constants (low capacitance equivalent thicknesses, CETs), they are attractive materials for the design and fabrication of compact, low-power devices. Replacing conventional dielectrics with ferroelectrics yields ferroelectric tunnel junctions (FTJs), nonvolatile ferroelectric random-access memory (FeRAM), and ferroelectric field-effect transistors (FeFETs) among other conceivable devices.

Tunnel junctions comprise two electrodes separated by a thin dielectric barrier, such that any current flowing between the electrodes may arise from quantum tunneling. When components of a tunnel junction have switchable electronic properties, corresponding modulations in the barrier potential may produce distinct device states with higher and lower tunneling resistances, i.e., an OFF state and an ON state.

Conventional magnetic tunnel junctions (MTJs) comprise ferromagnetic electrodes with independently switchable, stable magnetizations that may be anti-aligned (OFF) or aligned (ON). In FTJs, by contrast, the switchable component is a thin ferroelectric barrier that replaces the conventional dielectric; the remanent polarization may be opposed to (OFF) or aligned with (ON) the flow of current.

In FTJs, an applied voltage may nucleate and facilitate the growth of microscopic domains within the ferroelectric that have local dipole moments opposing the remanent polarization, yielding a smaller net polarization and a corresponding change in resistance. In this way, a multistate FTJ can be implemented. While analogous partial switching of magnetization may implement a multistate MTJ, states of the FTJ may be more clearly distinguishable. OFF/ON resistance ratios in binary FTJs may be as high as 104, for example, whereas the same ratio in binary MTJs may only be as high as 101.

Because biological synapses may also exhibit multistate behavior, FTJs are among the candidate devices for use as artificial synapses in physical neural networks and neuromorphic computing (such as reservoir computing). With greater industrial interest in these devices, so too is there a growing need for improved methods of integration for ferroelectrics.

### SUMMARY

In an embodiment, a method of forming a ferroelectric device includes forming a first electrode material layer over a substrate; forming a ferroelectric material layer over the first electrode material layer; forming a first non-ferroelectric material layer over the ferroelectric material layer; and forming a second electrode material layer over the first non-ferroelectric material layer, the second electrode material layer including tungsten, the ferroelectric device being formed by a stack including the first electrode material layer, the ferroelectric material layer, the first non-ferroelectric material layer, and the second electrode material layer.

In another embodiment, a method of forming a ferroelectric device includes depositing a first electrode layer over a substrate, the first electrode layer including tungsten; depositing a first oxide layer over the first electrode layer, the first oxide layer including silicon oxide or a metal oxide including aluminum, yttrium, zirconium, lanthanum, or gadolinium; depositing a hafnium zirconium oxide layer over the first oxide layer; and depositing a second electrode layer over the hafnium zirconium oxide layer.

In still another embodiment, a ferroelectric device includes a first electrode disposed over a substrate; a second electrode disposed over the first electrode, the second electrode including tungsten; and a dielectric stack disposed between the first electrode and the second electrode, the dielectric stack including a first oxide layer, a second oxide layer, and a ferroelectric material layer disposed between the first oxide layer and the second oxide layer.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1C illustrate cross-sectional views of embodiment devices, and in particular ferroelectric capacitors, comprising various metal-insulator-metal (MIM) structures, wherein FIG. 1A illustrates a capacitor with a dielectric stack comprising a second ferroelectric material layer disposed over a first ferroelectric material layer with a ferroelectric material layer disposed in between, wherein FIG. 1B illustrates a capacitor with a top-lined ferroelectric comprising a non-ferroelectric material layer disposed over a ferroelectric material layer, and wherein FIG. 1C illustrates a capacitor with a bottom-lined ferroelectric comprising a ferroelectric material layer disposed over a non-ferroelectric material layer, in accordance with various embodiments;

FIGS. 2A and 2B respectively provide representative voltage-polarization hysteresis loops for a device comprising a dielectric stack and a device omitting non-ferroelectric material layers, as well as corresponding plots of a leakage current from the devices, showing that the former device exhibits improved ferroelectric properties;

FIGS. 3A-3E illustrate cross-sectional views of the formation of a ferroelectric device comprising a dielectric stack, followed by formation of a contact via to an electrode of the device, wherein FIG. 3A illustrates a stack of material layers having been formed, wherein FIG. 3B illustrates the stack of material layers after an annealing process, wherein FIG. 3C illustrates deposition of a layer of electrode material over the existing stack, wherein FIG. 3D illustrates the result of patterning and etching the material layers to complete the ferroelectric device, and FIG. 3E illustrates the ferroelectric device after formation of the contact via, in accordance with various embodiments;

FIGS. 4A-4E illustrate cross-sectional views of the formation of a ferroelectric device comprising a dielectric stack and with crosspoint device geometry, followed by formation of a contact via to an electrode of the capacitor, wherein FIG. 4A illustrates a stack of material layers having been patterned and etched after formation of a stack of material layers and an annealing process (as in FIGS. 3A and 3B), wherein FIG. 4B illustrates deposition of an interlayer dielectric over the patterned stack of material layers, wherein FIG. 4C illustrates formation of a trench perpendicular to the patterned stack, wherein FIG. 4D illustrates formation of an electrode within the trench to complete the ferroelectric device, and FIG. 4E illustrates the ferroelectric device after formation of the contact via, in accordance with various embodiments;

FIGS. 5A-5E provide complementary top-down views of the formation of a ferroelectric device comprising a dielectric stack and with crosspoint device geometry, followed by formation of a contact via to an electrode of the device, in accordance with various embodiments; and

FIGS. 6A and 6B are flow charts for methods of forming a ferroelectric device, such as the ferroelectric devices illustrated in the preceding figures and other embodiment devices, wherein FIG. 6A describes a method comprising formation of a ferroelectric device such as that illustrated in FIG. 1A, and wherein FIG. 6B describes a method comprising formation of a ferroelectric device such as that illustrated in FIG. 1C, according to various embodiments.

### DETAILED DESCRIPTION OF ILLUSTRATIVE EMBODIMENTS

Pristine ferroelectric materials often have a small remanent polarization that grows over repeated switching, a phenomenon called “wake-up.” With continued use, Pᵣ reaches a peak and then begins to decrease again, signaling the onset of fatigue. Fatigue comes to an end when a leakage path forms in the ferroelectric and the associated device breaks down entirely.

Wake-up and fatigue stem from the same microscopic origin, namely, a field-modulated aging or ripening of the structure of the ferroelectric. Consequently, ferroelectric devices may be sought that exhibit improved electrical properties during wake-up, with a delayed onset of fatigue. Methods described herein enable the fabrication of such devices, according to various embodiments, by improving the electrical properties of a ferroelectric material layer subsequent to deposition and by protecting it from damage during integration.

These phenomena may be explained with reference to a specific ferroelectric material, such as hafnium zirconium oxide (HZO). HZO materials have a continuum of possible formulas HfₓZr₁₋ₓO₂ (0≤x≤1), with HfO₂ (hafnia, x=1) and other hafnium-rich compositions being conventional dielectrics; compositions with x≈0.5 (i.e., near-equal amounts of hafnium and zirconium) being ferroelectric; and zirconium-rich compositions and ZrO₂ (zirconia, x=0) being antiferroelectric, with a vanishing polarization at zero field. The properties of HZO may be tuned compositionally both by a choice of x and by doping with metals (such as aluminum, silicon, scandium, yttrium, niobium, lanthanum, or erbium) or non-metals (such as hydrogen, carbon, or nitrogen).

Ferroelectricity and antiferroelectricity in the latter HZO compositions originate in a bistability of their crystal structures. Below a critical temperature Tc, and in the absence of an electric field, two different arrangements of oxygens relative to the metal atoms are stable and energetically equivalent. When a field is applied, however, partial charges on each atom interact with the electric field to break this energetic symmetry, and one or the other arrangement (and the corresponding sign of a local dipole moment) will be preferred. Additional lattice-modulated interactions among these local dipoles lead to the formation of regions of predictable electrical ordering known as domains.

In ferroelectric materials, all of the local dipoles within a given domain are aligned with each other and may further align with or oppose an applied field. (In antiferroelectrics, by contrast, the local dipoles within domains are anti-aligned.) The remanent polarization Pᵣ or −Pᵣ may thus be attributed to the establishment of energetically stable arrangements—two polarization states, corresponding in some embodiments to the {OFF, ON} state space of FTJs—in which domains of one alignment dominate in number and/or size. Switching between these states may be accomplished by applying a field opposed to the remanent polarization and with a voltage above a certain critical magnitude (the coercive voltage, V_{c}).

As the strength of an applied field increases—and as more anti-aligned dipoles flip direction in order to minimize the energy of the ferroelectric—the polarization increases nonlinearly. (Fixing the field at a given strength may thus maintain the ferroelectric in a state with well-characterized polarization different in magnitude from Pᵣ, as may be desired for multistate FTJs.) For sufficiently high fields, domains comprising anti-aligned dipoles become negligible both in number and size, and the only way to increase the polarization within the ferroelectric is to increase the magnitude of the local dipoles. At this stage, the polarization saturates and changes linearly. Taken together, these phenomena account for the high dielectric constant of ferroelectric materials.

HZO films typically comprise a mixture of grains of three distinct phases: an antiferroelectric tetragonal (t) phase, a ferroelectric orthorhombic (o) phase, and a paraelectric monoclinic (m) phase. (Paraelectric materials have nonlinear polarization behavior when a field is applied but no remanent polarization and no microscopic ordering of local dipoles.) The t- and o-phases interconvert relatively freely, with the o-phase being slightly preferred for grains of larger size. Both t- and o-phases are significantly less stable than the m-phase as grains grow, but a large activation barrier tends to suppress interconversion—at least, as long as energy is not introduced into the system in the form of elevated temperatures or fields. In other words, switching provides energy that facilitates conversion of the t-phase to the o-phase and (ultimately) to the m-phase, initially improving the ferroelectric properties of the HZO material (wake-up) but inevitably leading to fatigue and breakdown. Increasing the abundance of t- and o-phase grains in the pristine material may therefore extend wake-up and delay the onset of fatigue.

An HZO film may initially have a deposition process-determined concentration of defects, particularly oxygen vacancies with a +2 charge (V_{O}²⁺). The presence of these vacancies encourages the formation of t-phase grains when HZO films are deposited. Advantageously, and in accordance with various embodiments, HZO films may be deposited by a process such as atomic layer deposition (ALD) with a timed dose of an oxidant, such as water, which tends to increase the concentration of vacancies.

Subsequent to deposition, HZO films may be annealed over (or while capped by) a material layer with an incommensurate structure (i.e., with a mismatched or misaligned lattice). Strain generated at the boundary between HZO and an incommensurate material due to thermal expansion during annealing further favors the formation of grains of the t- and o-phases. (Too much strain, however, may induce interfacial defects.) Advantageously, and in accordance with various embodiments, HZO films and other ferroelectric materials may be annealed while capped by a variety of incommensurate materials, including electrode materials.

Careful design of deposition and annealing protocols may considerably improve the grain structure (and thus the electrical properties) of ferroelectrics, according to various embodiments. At the same time, deposition of an incommensurate material directly over a ferroelectric using high-conformality processes appropriate for fabrication of advanced device structures-processes such as chemical vapor deposition (CVD) or ALD—may undermine these improvements. In particular, the use of metal halide precursors in a CVD or ALD may partially etch and roughen underlying ferroelectric material layers.

Etching of the ferroelectric may reduce overall device capacitance as well as the achievable remanent polarization, even after annealing. Roughening may lead to additional unpredictable changes in the interfacial structure and composition of the ferroelectric that negatively affect a variety of device characteristics (e.g., by supporting trap states and preventing formation of an ohmic contact). The increase in surface area that attends roughening may further exacerbate unwanted diffusion between the material layers. For example, metal atoms from the electrodes or dopants from the substrate may diffuse into the ferroelectric, degrading its properties unpredictably. Oxide anions may also diffuse out of some ferroelectrics, forming additional oxygen vacancies that may (over many device cycles) chain together to create leakage paths and short the device.

Because remanent polarizations may be reduced by the etching, the adverse consequences of an etched ferroelectric for the resulting device at time of fabrication may include a lower number of implementable states (for multistate FTJs) and decreased state distinguishability (for FTJs generally, as well as for ferroelectric memory and logic devices). Device endurance may be compromised as well, with fatigue and breakdown occurring after fewer switching cycles than in a device comprising an undamaged ferroelectric material layer of similar thickness.

Given that insufficient durability is presently a barrier to the widespread adoption of devices such as FTJs and FeRAM, electrode materials and processes for electrode deposition have been sought that avoid or mitigate the difficulties just described. A prevailing engineering solution to these problems has been use of titanium nitride (TiN) electrodes. TiN electrodes may be formed by CVD or ALD using non-halide precursors, adhere well to substrates, and exhibit relatively low resistivity for a metal compound. More importantly for ferroelectric devices, TiN forms clean interfaces with a variety of ferroelectric materials, reducing the abundance of interfacial defects (and thus the corresponding trap states) and providing an ohmic contact. Titanium also has a native oxide that forms and grows over a number of switching cycles that serves as a diffusion barrier for metal atoms that might otherwise enter the ferroelectric and for oxygen atoms that might otherwise leave.

An important tradeoff associated with the adoption of TiN electrodes, however, is a reduction in remanent polarization relative to comparable devices comprising metal electrodes. In other words, problems with durability are partially resolved at the cost of device performance. Other electrode materials may be desired that strike a better balance between device performance and device longevity.

Tungsten has excellent electrical properties, but in many other respects, it would seem to be a poor choice for the electrodes of a ferroelectric device. Tungsten is most commonly deposited using tungsten halide precursors such as tungsten hexafluoride (WF₆), tungsten tetrachloride (WCl₄), or tungsten (V) chloride (W₂Cl₁₀), resulting in both etching and roughening of the ferroelectric and leaving behind mobile halide ions that may diffuse into it. Moreover, tungsten has a smaller lattice constant than TiN (itself having a tighter lattice than HZO), meaning that interfacial defects and trap states may be more prevalent with tungsten electrodes. Tungsten is also more susceptible to oxidation than TiN, yet its oxide is less stable than that of titanium and may serve as a less effective diffusion barrier.

Various embodiments enable protecting a ferroelectric material layer from damage during integration with an electrode (and, in particular, a tungsten electrode) by disposing a non-ferroelectric material layer (such as an oxide layer) between them. The presence of a non-ferroelectric layer may have various other salutary effects, such as reducing diffusion of metals into the ferroelectric or of oxygen out of the ferroelectric, thereby compensating for the lesser ability of tungsten oxides to serve this function. In some embodiments, the non-ferroelectric layer may even serve as a source of oxygen to fill vacancies in the ferroelectric material layer, thereby improving the long-term reliability of embodiment devices.

Embodiment devices may also advantageously exhibit an increased effective field strength within the ferroelectric, enabling faster switching with lower power requirements, by virtue of improved screening of unbalanced charges at the ferroelectric surface that reduces the depolarization field generated within the bulk. Embodiment devices may further have a higher remanent polarization than can be achieved with TiN electrodes, such that state distinguishability is improved and the number of implementable states increases.

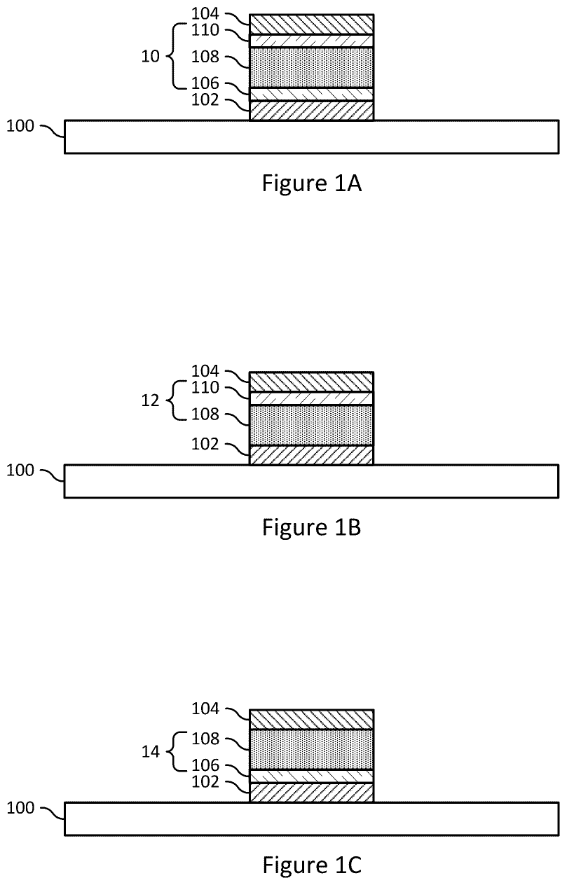

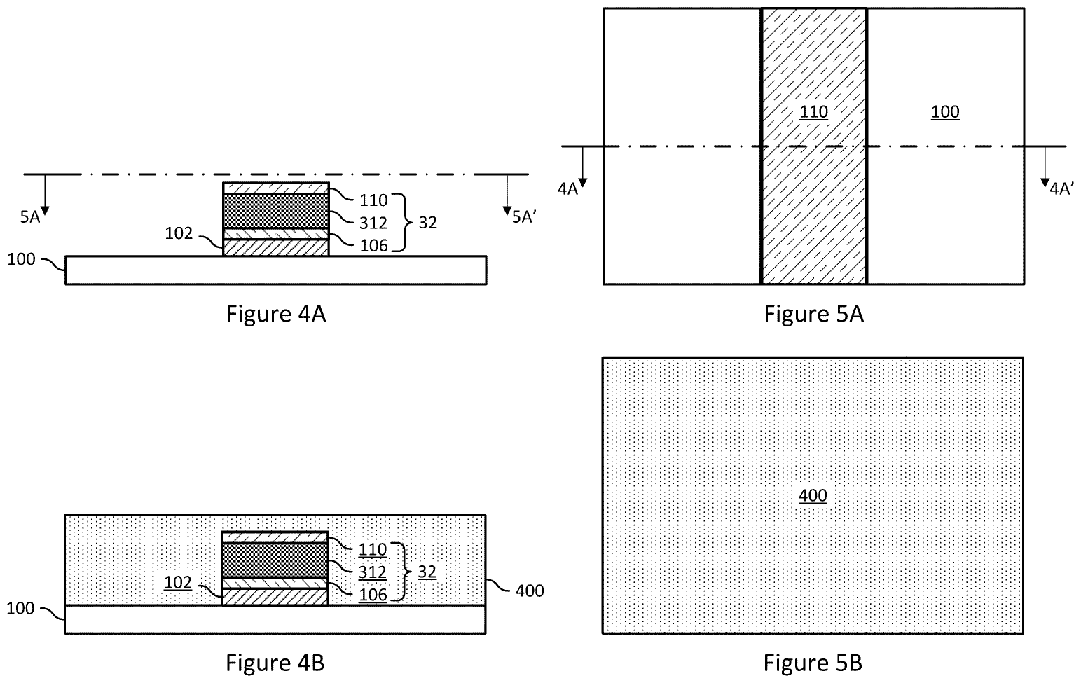

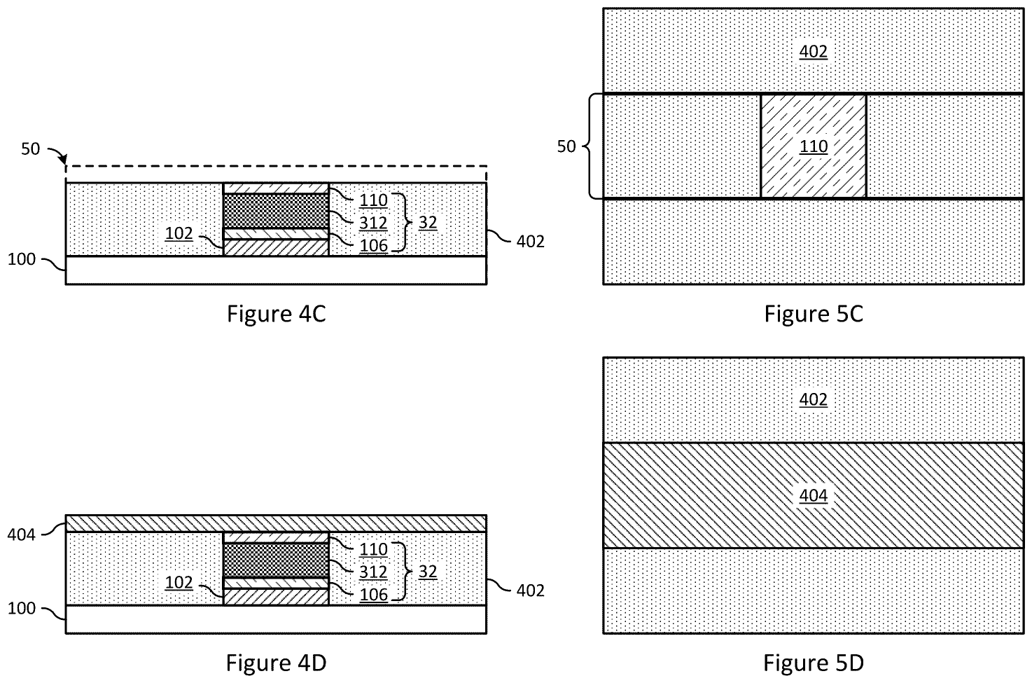

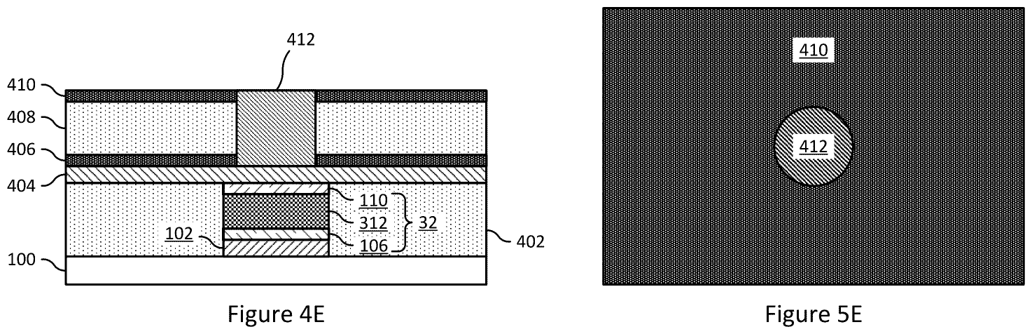

FIGS. 1A-1C illustrate cross-sectional views of embodiment devices, and in particular ferroelectric capacitors, comprising various MIM structures with a non-ferroelectric layer (such as an oxide layer) disposed between a ferroelectric material layer and an electrode. Because the embodiment device of FIG. 1A comprises the components of the other embodiment devices illustrated in FIGS. 1B and 1C, the description that follows focuses on this figure while noting any differences. An alternate device geometry consistent with various embodiments will be described separately below with reference to FIGS. 4A-4E and 5A-5E. Like reference numerals are used to label like components in the respective figures.

In FIG. 1A, and according to various embodiments, an embodiment device comprises a top electrode (or second electrode) 104 disposed over a bottom electrode (or first electrode) 102, with a dielectric stack 10 (described in further detail below) disposed in between. The embodiment device itself is disposed over a substrate 100. As shown in FIGS. 1A-1C, the bottom electrode 102 may be in direct physical contact with the substrate 100.

The substrate 100 represents generically any suitable semiconductor substrate being processed in accordance with embodiments. The substrate 100 may be a bulk substrate such as a semiconductor wafer, a semiconductor-on-insulator (SOI) wafer, or any of various other semiconductor substrates. According to various embodiments, the substrate 100 may comprise a semiconductor such as silicon, germanium, silicon germanium, silicon germanium carbide, or silicon carbide. In other embodiments, the substrate 100 may comprise a III-V semiconductor, such as gallium arsenide, gallium arsenic phosphide, gallium indium phosphide, indium arsenide, or indium phosphide.

The substrate 100 may be coated or layered with any number of additional materials, including semiconductors or compound semiconductors, metals or metalloids, metal or metalloid oxides, or metal or metalloid nitrides. In some embodiments, the substrate 100 may comprise an epitaxial layer disposed over a bulk semiconductor.

According to various embodiments, the substrate 100 may comprise a metal; a non-oxide semiconductor, such as silicon, silicon germanium, or a III-V semiconductor; an oxide semiconductor, such as indium gallium oxide, indium gallium zinc oxide, indium tin oxide, indium tungsten oxide, or zinc oxide; a 2D material, such as a transition metal dichalcogenide or graphene; a 1D material, such as carbon nanotubes; or any combination thereof.

The substrate 100 may include any material portion or structure of a device, particularly a semiconductor or other electronics device. Similarly, in some embodiments, the substrate 100 may itself be patterned or embedded in other components of a semiconductor structure or device, such as a reconstituted wafer in a wafer-level package process. In some such embodiments, the substrate 100 may include various device regions and isolation regions (such as shallow trench isolation regions), as well as other regions formed therein.

In various embodiments, the bottom electrode 102 may comprise an elemental metal, such as scandium, cobalt, nickel, zirconium, molybdenum, ruthenium, rhodium, hafnium, tungsten, or rhenium. In some embodiments, the bottom electrode 102 may comprise a suitable conductive material, including bilayer metals (such as Ni—Al), conductive nitrides (such as TiN or tantalum nitride), or conductive oxides such as tungsten oxide, iridium (IV) oxide, ruthenium (IV) oxide, lanthanum strontium cobalt oxide (LSCO), strontium ruthenium oxide (SRO), or lanthanum-doped SRO.

In still other embodiments, the bottom electrode 102 may comprise an elemental semiconductor, such as silicon or germanium; a compound semiconductor, such as silicon carbide, silicon germanium or a III-V semiconductor; an oxide semiconductor, such as indium gallium oxide, indium gallium zinc oxide, indium tin oxide, indium tungsten oxide, or zinc oxide; a 2D material, such as a transition metal dichalcogenide or graphene; a 1D material, such as carbon nanotubes; or any combination thereof. In some of these embodiments, the bottom electrode 102 may be incorporated into the substrate 100. In embodiments comprising a semiconductor, the bottom electrode 102 may comprise p-type dopants such as boron, gallium, or indium or n-type dopants such as phosphorus, arsenic, or antimony in concentrations sufficient to achieve metal-like conductivity.

The top electrode 104 may also comprise an elemental metal, a bilayer metal, a conductive oxide, a conductive nitride, or another suitable material, such as any of those described above, according to various embodiments. In accordance with embodiments, either or both of the bottom electrode 102 and the top electrode 104 comprise tungsten.

With further reference to FIG. 1A, the dielectric stack 10 may comprise a lower non-ferroelectric material layer 106 and an upper non-ferroelectric material layer 110, with a ferroelectric material layer 108 disposed between them. In the embodiment devices of FIGS. 1B and 1C, by contrast, a non-ferroelectric material layer may appear either above the ferroelectric material layer 108 or below it, but not both. FIG. 1B thus illustrates a top-lined ferroelectric 12 comprising the ferroelectric material layer 108 and the upper non-ferroelectric material layer 110 disposed above it (in direct physical contact with it and with the top electrode 104). FIG. 1C illustrates a bottom-lined ferroelectric 14 comprising the ferroelectric material layer 108 and the lower non-ferroelectric material layer 106 disposed below it (in direct physical contact with it and with the bottom electrode 102).

In various embodiments, the lower non-ferroelectric material layer 106 and the upper non-ferroelectric material layer 110 may each comprise a thickness typically thinner than the ferroelectric material layer 108 (as described below). In embodiments, a thickness of each non-ferroelectric material layer may be between 0.3 nm and 5 nm. For example, according to various embodiments, the thickness of a non-ferroelectric material layer may be between 0.5 nm and 5 nm; between 0.5 nm and 2 nm; between 0.5 nm and 1 nm; or between 0.3 nm and 3 nm.

In some embodiments, more than two layers of non-ferroelectric material may be present in the top-lined ferroelectric 12, the dielectric stack 10, or the bottom-lined ferroelectric 14. As long as non-ferroelectric material layers are disposed consistent with the respective illustrations in FIGS. 1A-1C, the numbers, compositions, and thicknesses of non-ferroelectric material layers may be selected in order to achieve target device characteristics. For example, the thicknesses of any non-ferroelectric materials present may be selected such that the total thickness of non-ferroelectric material layers disposed above (or below) the ferroelectric material layer 108 may still be between 0.3 nm and 5 nm.

The lower non-ferroelectric material layer 106 may comprise any suitable non-ferroelectric material. In various embodiments, the lower non-ferroelectric material layer 106 may comprise a metalloid oxide (such as silicon oxide) or a metal oxide, such that the lower non-ferroelectric material layer 106 may be an oxide layer. In embodiments with the lower non-ferroelectric material layer comprising a metal oxide, the metal oxide may comprise a metal such as aluminum, yttrium, zirconium, lanthanum, or gadolinium.

In other embodiments, the lower non-ferroelectric material layer 106 may comprise a conductive nitride. For example, the lower non-ferroelectric material layer 106 may comprise TiN or tantalum nitride. In still other embodiments, the lower non-ferroelectric material layer 106 may comprise a metal liner. In such embodiments, the metal liner may comprise aluminum, titanium, hafnium, or tantalum. Conductive nitrides and metal liners may serve as barriers to oxygen diffusion out of the ferroelectric material layer 108. Conductive nitrides may further form stable interfaces and ohmic contacts with the ferroelectric, and metal liners may further provide a nucleation layer and improved adhesion for the ferroelectric.

The upper non-ferroelectric material layer 110 may similarly comprise any suitable non-ferroelectric material, and may in various embodiments be an oxide layer comprising a metalloid oxide (such as silicon oxide), any of the metal oxides just described, or a conductive nitride or metal liner. The lower non-ferroelectric material layer 106 and the upper non-ferroelectric material layer 110 may comprise the same material, similar materials, or different materials, according to various embodiments.

In various embodiments, the ferroelectric material layer 108 may comprise HZO, with or without doping, with or without annealing (as described below), and in any of the antiferroelectric or ferroelectric compositions previously described. In such embodiments, a thickness of the ferroelectric material layer 108 may be between 1 nm and 20 nm. In some such embodiments, the thickness of the ferroelectric material layer 108 may be between 2 nm and 10 nm; in other such embodiments, the thickness of the ferroelectric material layer 108 may be between 4 nm and 10 nm.

In various other embodiments, the ferroelectric material layer 108 may comprise any dielectric material capable of forming ferroelectric phases. In some embodiments, the ferroelectric material layer 108 may comprise a perovskite, such as lithium niobate, barium titanate, bismuth ferrite, lead zirconate titanate (PZT), or lead magnesium niobate-lead titanate (PMN-PT); a layered perovskite such as strontium bismuth tantalate; a wurtzite, such as aluminum scandium nitride, aluminum boron nitride, or zinc magnesium oxide; or another compound, such as indium (III) selenide. In some embodiments, including some embodiments comprising HZO, the ferroelectric material layer 108 may comprise a bilayer or multi-layer structure; in certain of these latter embodiments, two or more layers may have the same elemental composition but different stoichiometry.

Embodiment devices may have various advantageous characteristics. For example, the inventors have fabricated devices comprising the dielectric stack 10 (per FIG. 1B) and found that they exhibit higher remanent polarization than devices comprising the bottom-lined ferroelectric 14 (per FIG. 1C). These latter embodiments (in turn) have higher remanent polarization than devices omitting non-ferroelectric material layers altogether.

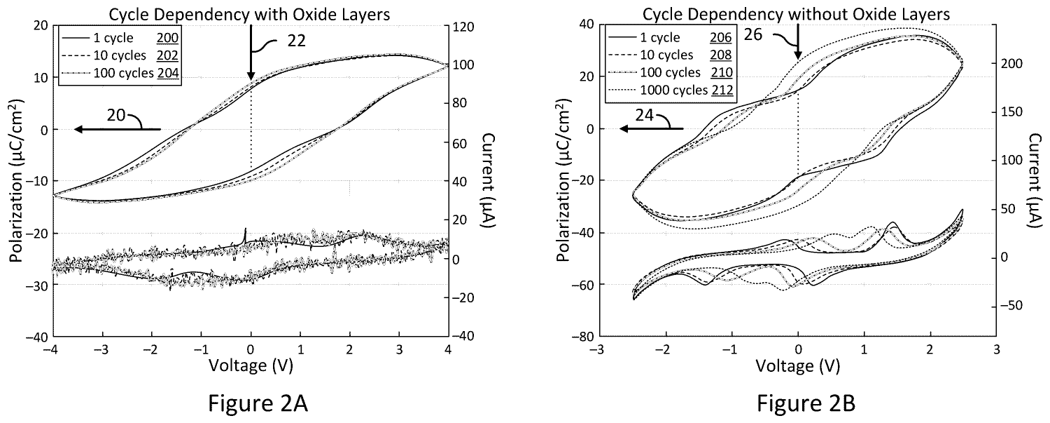

FIGS. 2A and 2B further illustrate advantageous properties of devices comprising the dielectric stack 10 as compared to devices omitting the lower and upper non-ferroelectric material layers 106 and 110. These figures present voltage-polarization hysteresis loops and leakage current loops for devices comprising a 5 nm-thick HZO layer with (FIG. 2A) and without (FIG. 2B) lower and upper non-ferroelectric material layers 106 and 110 comprising 2 nm-thick zirconia. Plots similar to those in FIGS. 2A and 2B may be produced by applying an AC driving voltage with magnitude Vₘₐₓ (typically between 1 V and 10 V) to the respective devices at a chosen frequency (10 kHz, for example) and smoothing the measured trajectories in the V-P plane (with polarizations typically in the tens of μC/cm²).

The device of FIG. 2A exhibits consistent ferroelectric behavior over 100 cycles, with the shapes of the hysteresis loops in the upper part of the figure changing only slightly as cycling proceeds from 1 cycle 200 (solid line) to 10 cycles 202 (half-dashed line) and then to 100 cycles 204 (outlined dots). The corresponding polarizations may be determined with reference the axis at left, as indicated by arrow 20; in particular, the remanent polarizations (P values at V=0, as indicated by arrow 22 and the accompanying half-dotted line) fall within a narrow range of magnitudes (between 7 μC/cm² and 10 μC/cm²). The leakage currents in the lower part of the figure remain within a magnitude of 20 μA and follow a fairly consistent trajectory in the V−i plane, apart from superimposed noise.

By contrast, the device of FIG. 2B exhibits significant cycle dependency in the shapes of measured V-P hysteresis loops, remanent polarizations, and leakage currents as cycling proceeds from 1 cycle 206 (solid line) to 10 cycles 208 (half-dashed line) to 100 cycles 210 (outlined dots) and then to 1000 cycles 212 (half-half-dashed line). In particular, the loop for 1 cycle 206 shows pronounced double hysteresis consistent with antiferroelectric properties, while the loop after 1000 cycles 212 is closer to single hysteresis. Remanent polarizations increase substantially as well, as may be determined with reference to the axis at left (as indicated by arrows 24 and 26 and the accompanying half-dotted line); the magnitude of Pᵣ increases from as low as 16 μC/cm² after 1 cycle 206 to as high as 30 μC/cm² after 1000 cycles 212. The leakage currents in the lower part of the figure remain within a much larger magnitude of 55 μA and do not follow a consistent trajectory in the V−i plane. The variability of these device characteristics within a single device (and across an ensemble of devices) may pose challenges both at the design stage and for developing operating protocols that remain workable over the lifetime of a device.

The device of FIG. 2A exhibits lower remanent polarization than the device of FIG. 2B (and comparable coercive fields), but that fact is not inconsistent with embodiment devices having advantageous properties. Relative to the device of FIG. 2B (comprising 5 nm-thick HZO with dielectric constant k˜ 20), the device of FIG. 2A comprises an additional 4 nm of zirconia (k˜ 25), nearly doubling the thickness of the associated dielectric stack 10. Voltage division across the zirconia layers reduces the effective field strength in the ferroelectric considerably, with a concomitant reduction in Pᵣ. In embodiments comprising either or both of the lower and upper non-ferroelectric material layers 106 and 110 with a total thickness much smaller than that of the ferroelectric material layer 108, the presence of the non-ferroelectric material layers may make a minor (or even negligible) contribution to the thickness and effective k of the dielectric, enabling simultaneous improvements in the remanent polarization and the cycle dependency.

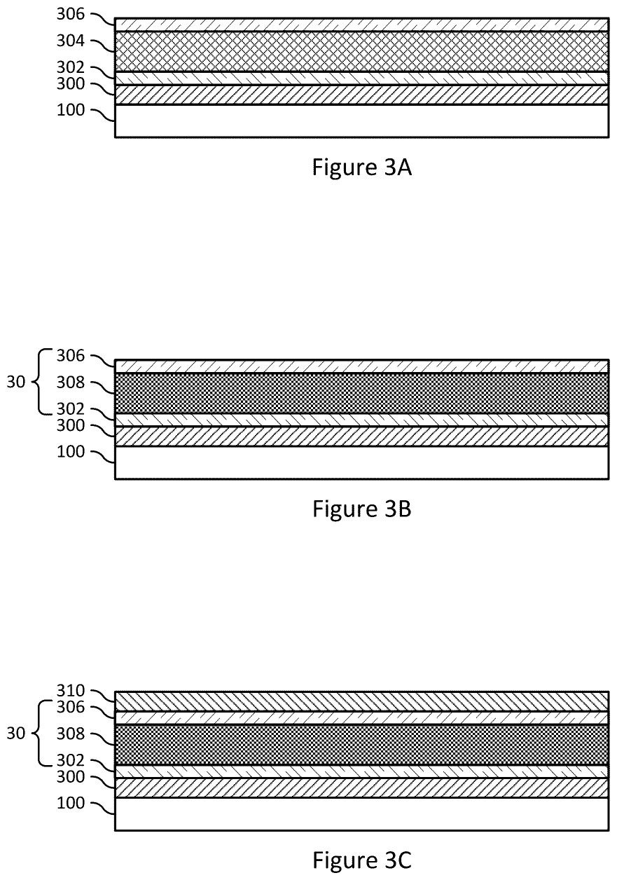

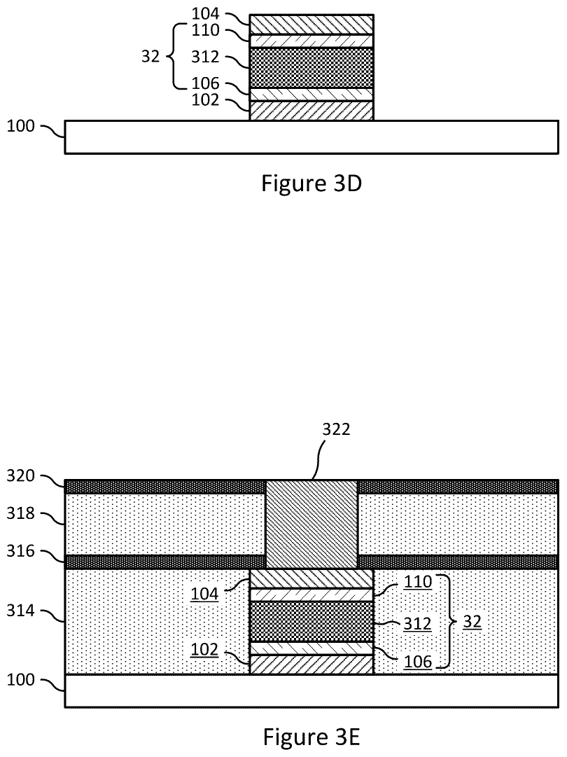

FIGS. 3A-3E illustrate cross-sectional views of the formation of a ferroelectric device comprising a dielectric stack, corresponding to an embodiment device of the type illustrated in FIG. 1A, followed by formation of a contact via to an electrode of the device. (Embodiment devices depicted in FIG. 1B or 1C may be obtained by omitting a formation step for the corresponding non-ferroelectric material layer.) The cross-sectional view in FIGS. 3A-3E is consistent with the views presented in FIGS. 1A-1C; consequently, like reference numerals are used to refer to identical features in the two sets of figures.

With reference to FIG. 3A, a layer stack results from the successive formation of a first electrode material layer 300 over the substrate 100; formation of a lower non-ferroelectric material layer 302 over the first electrode material layer 300; formation of a ferroelectric material layer 304 over the lower non-ferroelectric material layer 302; and formation of an upper non-ferroelectric material layer 306 over the ferroelectric material layer 304.

The first electrode material layer 300 may comprise any of the electrode materials previously described (such as tungsten) and may be deposited using any suitable deposition technique. For example, the first electrode material layer 300 may be formed using physical vapor deposition (PVD) methods such as sputtering, evaporation, or molecular beam evaporation; pulsed laser deposition (PLD); ALD; CVD; plasma-enhanced ALD or CVD; metal-organic CVD; low-pressure CVD; rapid thermal CVD; or any other layer deposition process or combination thereof. A thickness of the first electrode material layer 300 may be between 5 nm and 100 nm, according to various embodiments.

The lower non-ferroelectric material layer 302 may comprise any of the non-ferroelectric materials previously described and may be deposited using any suitable deposition technique, such as any of those just described for the first electrode material layer 300. A thickness of the lower non-ferroelectric material layer 302 may be between 0.3 nm and 5 nm, in accordance with the various embodiments described above. In the fabrication of embodiments comprising the top-lined ferroelectric 12 of FIG. 1B, the lower non-ferroelectric material layer 302 may be omitted.

The ferroelectric material layer 304 may comprise any of the ferroelectric materials previously described and may be deposited using any suitable deposition technique, such as ALD, CVD, PVD, sol-gel deposition, or any other layer deposition process or combination thereof. A thickness of the ferroelectric material layer 304 may be between 1 nm and 20 nm, according to various embodiments.

In some embodiments, the ferroelectric material layer 304 may exhibit voltage-polarization hysteresis consistent with ferroelectricity or antiferroelectricity to some extent after it has been deposited. In other embodiments, depending on composition, stoichiometry, and method and conditions of deposition, the layer deposited may instead be a material layer capable of forming an annealed ferroelectric material layer 308 subsequent to further processing. In some such embodiments, the material layer deposited may be an amorphous layer that crystallizes when annealed (using any of the methods described below) to yield a microscopic structure with ferroelectric properties.

In various embodiments, the ferroelectric material layer 304 may comprise any of the continuum of stoichiometries of HZO, HfₓZr₁₋ₓO₂ with 0≤x≤1. In some embodiments, the ferroelectric material layer 304 may comprise ferroelectric or antiferroelectric stoichiometries, HfₓZr₁₋ₓO₂ with 0≤x≈0.5. HZO stoichiometries may be understood as comprising 100× mol % HfO₂ and 100(1−x) mol % ZrO₂; accordingly, and in various embodiments, the ferroelectric material layer 304 comprising HZO may have mole percentages of HfO₂ and ZrO₂ above threshold values for forming a ferroelectric phase after deposition (or after subsequent annealing). According to certain embodiments, the HfO₂ and ZrO₂ mole percentages may both be at least 25 mol %. For example, HfO₂:ZrO₂ mole percentages may be 25 mol %:75 mol %, 30 mol %:70 mol %, 40 mol %:60 mol %, 50 mol %:50 mol %, 60 mol %:40 mol %, 70 mol %:30 mol %, 75 mol %:25 mol %, or another combination of mole percentages falling between those enumerated.

In various embodiments, the ferroelectric material layer 304 may comprise HZO deposited by ALD. According to some such embodiments, the ferroelectric material layer 304 may comprise a laminate of alternating HfO₂ and ZrO₂ layers; in other such embodiments, the ferroelectric material layer 304 may comprise a solid solution of a mixture of HfO₂ and ZrO₂.

In ALD processes for HZO, pulses of hafnium and/or zirconium precursors may be introduced into a deposition chamber, typically at temperatures between 200° C. and 400° C. and at low pressures, e.g., between 0.1 torr and 10 torr. Each precursor pulse may be followed by a purge step to remove excess precursors and byproducts, and to prevent gas-phase mixing of precursors and an oxidant to be introduced subsequently. After a precursor pulse and purge step, an oxidant pulse introduces oxygen to oxidize the metal surface, followed by a further purge step to remove organics or other byproducts from the surface.

In various embodiments, precursors for hafnium may comprise hafnium tetrachloride (HfCl₄) or a metal-organic compound. Metal-organic hafnium precursors may include compounds such as tetrakis(dimethylamido) hafnium (Hf(NMe₂)₄, TDMAH), tetrakis(ethylmethylamido) hafnium (Hf(NEtMe)₄, TEMAH), tetrakis(diethylamido) hafnium (Hf(NEt₂)₄, TDEAH), hafnium tert-butoxide (Hf(O^{t}Bu)₄, HTB), and tris(dimethylaminocyclopentadienyl) hafnium (HfCp(NMe₂)₃.

In various embodiments, precursors for zirconium may comprise zirconium tetrachloride (ZrCl₄) or a metal-organic compound. Metal-organic zirconium precursors may include compounds such as tetrakis(dimethylamido) zirconium (Zr(NMe₂)₄, TDMAZ), tetrakis(ethylmethylamido) zirconium (Zr(NMeEt)₄, TEMAZ), tetrakis(diethylamido) zirconium (Zr(NEt₂)₄, TDEAZ), zirconium tert-butoxide (Zr(O^{t}Bu)₄, ZTB), and tris(dimethylaminocyclopentadienyl) zirconium (ZrCp(NMe₂)₃.

In various embodiments, the oxidant may comprise water vapor (HZO), ozone (O₃), oxygen (O₂), or another oxygen-containing gas; in some embodiments, the oxidant may be plasma-excited. The purge gas may comprise any suitable gas that does not react with the selected precursors or with HZO; according to various embodiments, the purge gas may comprise nitrogen (N₂), argon, or helium.

According to one embodiment ALD process, a first plurality of cycles of ALD may comprise m cycles (integer m≥1) of sequential pulses of a hafnium precursor; a purge gas; an oxidant; and a purge gas in order to deposit HfO₂. Each pulse of the hafnium precursor and the oxidant may be performed for a time period that results in a saturation exposure on a target surface, e.g., an upper surface of the first electrode material layer 300 or of the lower non-ferroelectric material layer 302.

According to another embodiment ALD process, a first plurality of cycles of ALD may comprise n cycles (integer n≥1) of sequential pulses of a zirconium precursor; a purge gas; an oxidant; and a purge gas in order to deposit ZrO₂. Each pulse of the zirconium precursor and the oxidant may be performed for a time period that results in a saturation exposure on a target surface, e.g., an upper surface of the first electrode material layer 300 or of the lower non-ferroelectric material layer 302.

According to other embodiments, a ferroelectric material layer 304 comprising HZO may be deposited by sequentially performing m cycles of ALD depositing HfO₂ and n cycles of ALD depositing ZrO₂ in a supercycle that may be performed l times (integer l≥1) to form a laminate of alternating HfO₂ and ZrO₂ layers (with the lowest layer of the laminate comprising HfO₂). Alternately, the order of hafnium- and zirconium-depositing cycles in the supercycle may be reversed, thereby forming a laminate with the lowest layer comprising ZrO₂.

According to still other embodiments, a first plurality of cycles of ALD may comprise j cycles of sequential pulses (integer j≥1) of a mixture of a hafnium precursor and a zirconium precursor; a purge gas; an oxidant; and a purge gas in order to deposit a solid solution of a mixture of HfO₂ and ZrO₂. Each co-exposure pulse of the precursors and each pulse of the oxidant may be performed for a time period that results in a saturation exposure on a target surface, e.g., an upper surface of the first electrode material layer 300 or of the lower non-ferroelectric material layer 302.

The composition of the ferroelectric material layer 304 comprising HZO may be controlled by adjusting the number, duration, and other parameters of the hafnium and zirconium precursor pulses. For example, in embodiments comprising deposition of a solid solution of a mixture of HfO₂ and ZrO₂, the composition may be selected by independently controlling flow rates of the hafnium precursor and the zirconium precursor.

Steric hindrance between ligands of the hafnium or zirconium precursor and the oxidant, and a relatively few bonding sites available, may serve as a bottleneck for chemisorption on the surface. Consequently, the growth rate of a film of HfO₂, ZrO₂, or a solid solution of a mixture of HfO₂ and ZrO₂ may be less than a monolayer per cycle, and an ALD cycle (or plurality thereof) may be repeated until the desired film thickness is achieved.

Thicknesses of HfO₂ and ZrO₂ layers in an HZO laminate may be the same in some embodiments; in other embodiments, the relative thicknesses of HfO₂ and ZrO₂ layers may have a constant ratio corresponding to a desired composition for the ferroelectric material layer 304. In still other embodiments, thicknesses of individual layers in a laminate may vary from layer to layer in order to achieve a structured change in composition across the ferroelectric material layer 304. For example, in some embodiments, thicknesses of individual layers in a laminate may be chosen to yield an approximation to a smooth gradient of composition across the ferroelectric material layer 304. Similarly, in embodiments comprising deposition of a solid solution of a mixture of HfO₂ and ZrO₂, flow rates of the hafnium precursor and the zirconium precursor may be held at a constant ratio (in some embodiments) or varied between pulses (in other embodiments).

Irrespective of whether the ferroelectric material layer 304 comprises HZO or how it may be structured, its thickness may be between 1 nm and 100 nm, according to various embodiments. For example, in embodiments, the thickness of the ferroelectric material layer 304 may be between 1 nm and 20 nm.

With further reference to FIG. 3A, the upper non-ferroelectric material layer 306 may comprise any of the non-ferroelectric materials previously described and may be deposited using any suitable deposition technique, such as any of those described for the first electrode material layer 300. In some embodiments, the upper non-ferroelectric material layer 306 may be deposited by vapor deposition, such as by CVD or ALD. A thickness of the upper non-ferroelectric material layer 306 may be between 0.3 nm and 5 nm, in accordance with the various embodiments described above. In the fabrication of embodiments comprising the bottom-lined ferroelectric 14 of FIG. 1C, the upper non-ferroelectric material layer 306 may be omitted.

In various embodiments, and as illustrated in FIG. 3B, a next step may be annealing of the ferroelectric material layer 304 to form an annealed ferroelectric material layer 308 in an annealed dielectric stack 30, thereby establishing or enhancing the properties of a ferroelectric phase in the annealed ferroelectric material layer 308. In other embodiments, annealing may be deferred until after any of the subsequent steps to be described, as long as a thermal or electromagnetic annealing method selected may be used without compromising the structural integrity or other properties of a device in fabrication at the corresponding stage.

Annealing methods may include rapid thermal processing, furnace annealing, laser annealing, microwave annealing, RF annealing, electric field (E-field) annealing, magnetic field (H-field) annealing, or other annealing methods consistent with a thermal budget for the respective embodiments. In various embodiments, the annealing may be performed at a temperature between 200° C. and 300° C., between 300° C. and 400° C., between 400° C. and 500° C., between 200° C. and 500° C., or between 400° C. and 900° C. In some embodiments, the annealing may be performed under vacuum conditions in the presence of an inert gas such as nitrogen (N₂) or argon.

In one embodiment, a rapid thermal process may be performed at temperatures between 300° C. and 550° C. for a duration between 1 second and 600 seconds. In another embodiment, the rapid thermal process may be performed at 500° C. for 30 seconds. In still another embodiment, furnace annealing may be applied, with the device in fabrication heated at 400° C. for 1 hour.

Other embodiments may use alternative annealing methods, such as microwave annealing at 2.45 GHz and between 500 W and 3 kW of power for 30 seconds to 5 minutes or RF annealing at 13.56 MHz between 100 W and 1 kW of power for 10 seconds to 2 minutes. Some embodiments may use E-field annealing with a field strength between 1 MV/cm to 10 MV/cm for 5 seconds to 600 seconds, the duration of the annealing being divided among electric field pulses with duration between 1 ms and 100 ms.

Annealing may reform the structure of the ferroelectric material layer 304 to yield an annealed ferroelectric material layer 308 with improved homogeneity, grain structure, remanent polarization, and/or other characteristics. From a structural standpoint, and as illustrated in FIG. 3B, the device in fabrication may look identical (or nearly so). Microscopic changes in the structure of the annealed ferroelectric material layer 308 may be significant for device properties, however, meriting a change in pattern fill.

Next, and with reference to FIG. 3C, a second electrode material layer 310 may be deposited that comprises any of the electrode materials previously described and a thickness between 5 nm and 100 nm, according to various embodiments. (according to various embodiments). The first electrode material layer 300 may be deposited using any technique compatible with the substrate 100; by contrast, in embodiments omitting the upper non-ferroelectric material layer 306, the particular method selected for deposition of the second electrode material layer 310 may be of great significance for the structure and properties of the annealed ferroelectric material layer 308, its interface with the second electrode material layer 310, the possibility of formation of an ohmic contact between these layers, and so on.

In such embodiments, corresponding to formation of a ferroelectric device of the type illustrated in FIG. 1C, the annealed ferroelectric material layer 308 may be unprotected from potential damage during formation of the second electrode material layer 310. In particular, and as described above, the use of high-conformality CVD or ALD methods comprising metal halide precursors may etch, roughen, and generally degrade the annealed ferroelectric material layer 308, compromising performance of the resulting ferroelectric device. This damage may only partially be compensated by the presence of the lower non-ferroelectric material layer 302, which may still advantageously serve as a diffusion barrier, help to reduce the depolarization field in the annealed ferroelectric, etc.

Therefore, in embodiments forming a ferroelectric device of the type illustrated in FIG. 1C, the second electrode material layer 310 may be formed by vapor deposition methods comprising a non-halide precursor such as a carbonyl precursor. In some embodiments, a second electrode material layer 310 comprising tungsten may be deposited by exposure to vapor comprising a tungsten carbonyl precursor such as tungsten hexacarbonyl (W(CO)₆); in other embodiments, a second electrode material layer 310 comprising molybdenum may be deposited by exposure to vapor comprising molybdenum hexacarbonyl (Mo(CO)₆). Carbonyl precursors suitable for use in an embodiment need not be hexacoordinate or octahedral; any convenient carbonyl complex of a selected metal may be used, such as (for example) dirhenium decacarbonyl (Re₂(CO)₁₀) for deposition of rhenium.

In other embodiments, the second electrode material layer 310 may be formed by vapor deposition methods comprising a non-halide precursor such as a metal-organic precursor. In some embodiments, a second electrode material layer 310 comprising tungsten may be deposited by exposure to vapor comprising a tungsten metal-organic precursor such as bis(tert-butylimido)bis(dimethylamido) tungsten (W(N^{t}Bu)₂(NMe₂)₂); in other embodiments, a second electrode material layer 310 comprising molybdenum may be deposited by exposure to vapor comprising bis(tert-butylimido)bis(dimethylamido) molybdenum (Mo(N^{t}Bu)₂(NMe₂)₂). Metal-organic precursors suitable for use in an embodiment need not follow the structural template provided by these named tungsten and molybdenum precursors; any convenient metal-organic precursor may be used, such as (for example) bis(ethylcyclopentadienyl)ruthenium (Ru(EtCp)₂) for deposition of ruthenium.

Embodiments comprising an upper non-ferroelectric material layer 306, corresponding to devices such as those illustrated in FIGS. 1A and 1B, may in some cases still comprise deposition of a second electrode material layer 310 using non-halide precursors as described above. Advantageously, however, the second electrode material layer 310 may cover the annealed ferroelectric material layer 308—or the ferroelectric material layer 304, in embodiments comprising deferred annealing or omitting annealing altogether—and thereby protect it from damage during formation of the second electrode material layer 310 and any subsequent process steps. Such protection may enable greater flexibility in the deposition chemistry selected for the second electrode material layer 310.

For example, it may be desirable in the context of a given manufacturing process to form a second electrode material layer 310 by vapor deposition using a metal halide precursor, such as deposition of tungsten using tungsten tetrafluoride (WF₄), tungsten tetrachloride (WCl₄), tungsten hexafluoride (WF₆), tungsten hexachloride (WCl₆), or tungsten (V) chloride (W₂Cl₁₀). Halogen-containing precursors may etch, roughen, or otherwise damage the annealed ferroelectric material layer 308 (or the ferroelectric material layer 304) in respective embodiments not comprising the upper non-ferroelectric material layer 306. According to other embodiments, however, an upper non-ferroelectric material layer 306 may be selected to comprise (for example) a metal oxide known to resist etching under exposure to tungsten halide precursors during formation of the second electrode material layer 310, thereby advantageously preventing or mitigating etching, roughening, and other damage. In embodiments comprising a second electrode material layer 310 comprising tungsten, aluminum (III) oxide (Al₂O₃) may be among various advantageously protective choices for the upper non-ferroelectric material layer 306.

The presence of the upper non-ferroelectric material layer 306 and the resulting protection of the annealed ferroelectric material layer 308 (or the ferroelectric material layer 304) may also enable deposition schemes resulting in devices with advantageous properties. For example, both metal halide precursors and non-halide precursors may be used in various combinations and sequences in order to prepare second electrode material bilayers or multi-layers, which may reduce the resistivity of the resulting electrode.

The second electrode material layer 310 having been deposited, the stack of material layers depicted in FIG. 3C forms components of a ferroelectric device—as illustrated, a ferroelectric capacitor. In particular, the combination of the first electrode material layer 300, the annealed ferroelectric material layer 308 (or the ferroelectric material layer 304, in embodiments deferring or omitting annealing), the upper non-ferroelectric material layer 306, and the second electrode material layer 310 may be understood as forming certain embodiment devices that may rely on the various advantageous and protective properties associated with the upper non-ferroelectric material layer 306. Other embodiment devices, particularly those corresponding to FIG. 1C, may be constituted differently.

The various layers described and illustrated with reference to FIGS. 3A-3C may be deposited in one or more vacuum chambers, according to various embodiments. In some such embodiments, the ferroelectric material layer 304, the upper non-ferroelectric material layer 306, and the second electrode material layer 310 may be deposited in one or more vacuum chambers without air exposure between deposition steps. Some embodiments may comprise performing various of the deposition steps and/or annealing processes contemplated above within a clustered system, ensuring (for example) that the device in fabrication may be held between deposition steps in an inert atmosphere with rigorously controlled concentrations of impurities.

With reference to FIG. 3D, the layer stack of FIG. 3C may be patterned and etched to form a ferroelectric device, which may (in some embodiments) be a ferroelectric capacitor such as the embodiment device of FIG. 1A. Patterning may be performed using any suitable lithography technique, such as dry lithography (e.g., using 193-nanometer dry lithography), immersion lithography (e.g., using 193-nanometer immersion lithography), i-line lithography (e.g., using 365-nanometer wavelength UV radiation for exposure), H-line lithography (e.g., using 405-nanometer wavelength UV radiation for exposure), extreme UV (EUV) lithography, high numerical aperture EUV (high NA-EUV), or deep UV (DUV) lithography. Following the lithography, any anisotropic etching method, such as reactive ion etching, may be used to etch the ferroelectric device.

Patterning and etching may result in the formation of distinct structural components within the ferroelectric device. In particular, and as shown in FIG. 3D (cf. FIG. 1A), the ferroelectric device may comprise the top electrode 104 disposed over the bottom electrode 102, with a patterned and annealed dielectric stack 32 disposed in between, with the device itself being disposed over the substrate 100. The patterned and annealed dielectric stack 32 comprises in turn a lower non-ferroelectric material layer 106 and an upper non-ferroelectric material layer 110 with a patterned and annealed ferroelectric material layer 312 disposed in between. A width (e.g., a critical dimension) of the ferroelectric device may be between 30 nm and 300 nm, in various embodiments. In some embodiments, the critical dimension may be between 30 nm and 60 nm. In embodiments (not illustrated) in which a single device or a line of spatially separated devices may be desirable rather than a linear device, additional patterning and etching may be carried out.

Further process steps may form a contact via 322 over the ferroelectric device, resulting in the integrated device illustrated in FIG. 3E. Formation of the contact via 322 may proceed (in various embodiments) by any conventional method; possibilities corresponding to various embodiments are briefly outlined below.

A first interlayer dielectric 314 may be deposited over the ferroelectric device. The first interlayer dielectric 314 may comprise silicon oxide, silicon nitride, silicon oxynitride, or another high-k dielectric material, in various embodiments. Alternatively, the first interlayer dielectric 314 may comprise a low-k dielectric material such as organo- or fluorosilicate glass, a porous dielectric such as black diamond (BD1, BD2, or BD3 forms of SiOC:H), or a polymer dielectric. The first interlayer dielectric 314 may be deposited using any suitable deposition technique, such as metal-organic CVD using tetraethyl orthosilicate (TEOS) in the case of silicon oxide.

Following the deposition of the first interlayer dielectric 314, a first etch stop layer 316, a second interlayer dielectric 318, and a second etch stop layer 320 may be sequentially deposited. The etch stop layers 316 and 320 may comprise any suitable material, such as silicon nitride, while the second interlayer dielectric 318 may comprise any of the materials described for the first interlayer dielectric 314. These layers may be deposited using any suitable deposition techniques, such as those described above.

A channel may then be patterned and etched sequentially through the second etch stop layer 320, the second interlayer dielectric 318, and the first etch stop layer 316 to form a channel revealing an upper surface of the top electrode 104. Patterning techniques used may include any lithographic technique described above. The first and second etch stop layers 316 and 320 may be etched by wet etching (or another isotropic etching method) with a chemistry selective toward these layers. In some embodiments, the wet etch chemistry may comprise hot phosphoric acid. The second interlayer dielectric 318 may be etched by an anisotropic etching method such as reactive ion etching, according to an embodiment.

A contact material may next be deposited by any suitable method to fill the channel and further to cover an upper surface of the second etch stop layer 320. The contact material may be any appropriate metallization element, such as any of the electrode materials described previously. The contact material may then be planarized (such as by chemical-mechanical planarization) to form the contact via 322, completing integration of the ferroelectric device.

The process flow just described with reference to FIGS. 3A-3E represents one of a variety of possible embodiments. Alternative embodiments may involve deferring the annealing step resulting in the structure of FIG. 3B until after deposition of the second electrode material layer 310 (cf. FIG. 3C), or until after patterning and etching (cf. FIG. 3D), for example. Other alternative embodiments may involve more significant departures from the process depicted in FIGS. 3A-3E; for example, other device geometries may be desirable.

FIGS. 4A-4E thus illustrate cross-sectional views of the formation of a ferroelectric device comprising a dielectric stack and with crosspoint device geometry, followed by formation of a contact via to an electrode of the capacitor. FIGS. 5A-5E present complementary top-down views, with the relationship between the two sets of figures being indicated by sectioning line 5A-5A′ in FIG. 4A and by sectioning line 4A-4A′ in FIG. 5A.

FIGS. 4A and 5A illustrate an alternate way forward from the structure of FIG. 3B. Rather than proceeding directly to the formation of the second electrode material layer 310 (as in FIG. 3C), patterning and etching may be performed using any of the methods described above with reference to FIGS. 3D and 3E (in various embodiments). The result of the patterning and etching may be the linear structure illustrated in FIG. 5A. A width (e.g., a critical dimension) of the linear structure may be between 30 nm and 300 nm, in various embodiments. In some embodiments, the critical dimension may be between 30 nm and 60 nm.

Next, as depicted in FIGS. 4B and 5B, an interlayer dielectric blanket 400 may be deposited to cover the linear structure of FIGS. 4A and 5A, with a thickness of the interlayer dielectric blanket 400 above an upper surface of the upper non-ferroelectric material layer 110 being at least equal to a target thickness of the top electrode to be formed subsequently (see FIGS. 4D and 5D). The interlayer dielectric blanket 400 may have the composition described previously with reference to FIG. 3E and may be deposited using any suitable deposition technique, such as those described above. In an embodiment, the interlayer dielectric blanket 400 may be silicon oxide deposited by metal-organic CVD using TEOS.

In FIGS. 4B and 5B, a trench 50 may be patterned and etched in the interlayer dielectric blanket 400 to yield a trenched dielectric 402. According to various embodiments, the trench 50 may be patterned by any suitable lithographic technique described above (comprising in some embodiments use of a hard mask such as silicon nitride) and may be etched by any anisotropic etching method, such as reactive ion etching. A resulting width of the trench 50 may be between 10 nm and 500 nm, and the depth of the trench 50 may be between 5 nm and 100 nm, according to various embodiments, to accommodate the target thickness of the top electrode.

As illustrated, and according to some embodiments, the trench 50 is orthogonal to the underlying device components, e.g., to the upper non-ferroelectric material layer 110, and will thus form a ferroelectric device with crosspoint geometry. In other embodiments, however, another relative orientation of the trench 50 may be chosen.

With continued reference to the orthogonal geometry of FIGS. 4B and 5B, the trench 50 may be sufficiently deep that it reveals an upper surface of the upper non-ferroelectric material layer 110. In embodiments comprising the trench 50 having the same width (critical dimension) as the underlying device components, opening of the trench 50 reveals an upper surface of the upper non-ferroelectric material layer 110 with a square cross section.

With reference to FIGS. 4D and 5D, a second electrode material layer may next be deposited, filling the trench 50 to cover the upper non-ferroelectric material layer 110 and further covering an upper surface of the trenched dielectric 402, before undergoing (in various embodiments) chemical-mechanical planarization or atomic layer etching to yield a top electrode 404 flush with an upper surface of the trenched dielectric 402. The top electrode 404 may comprise any of the electrode materials and may be deposited by any of methods described above, according to various embodiments.

Further process steps may form a contact via 412 over the ferroelectric device, resulting in the integrated device illustrated in FIGS. 4E and 5E. Formation of the contact via 412 may proceed (in various embodiments) by any conventional method, such as those possibilities described above with reference to FIG. 3E, and as described below for various embodiments.

First steps in formation of the contact via 412 may be sequential deposition of a first etch stop layer 406, an interlayer dielectric 408, and a second etch stop layer 410. The etch stop layers 406 and 410 may comprise any suitable material, such as silicon nitride, while the interlayer dielectric 408 may comprise any of the materials described above for the first interlayer dielectric 314. These layers may be deposited using any suitable deposition techniques, such as those described above.

A channel may then be patterned and etched sequentially through the second etch stop layer 410, the interlayer dielectric 408, and the first etch stop layer 406 to form a channel revealing an upper surface of the top electrode 404. (While a cross section of the channel illustrated in FIG. 5E is circular, any desirable shape may be patterned and etched in a given embodiment.) Patterning techniques used may include any lithographic technique described above. The first and second etch stop layers 406 and 410 may be etched by wet etching (or another isotropic etching method) with a chemistry selective toward these layers. In some embodiments, the wet etch chemistry may comprise hot phosphoric acid. The interlayer dielectric 408 may be etched by an anisotropic etching method such as reactive ion etching, according to an embodiment.

A contact material may next be deposited by any suitable method to fill the channel and further to cover an upper surface of the second etch stop layer 410. The contact material may be any appropriate metallization element, such as any of the electrode materials described previously. The contact material may then be planarized (such as by chemical-mechanical planarization) to form the contact via 412, completing integration of the ferroelectric device.

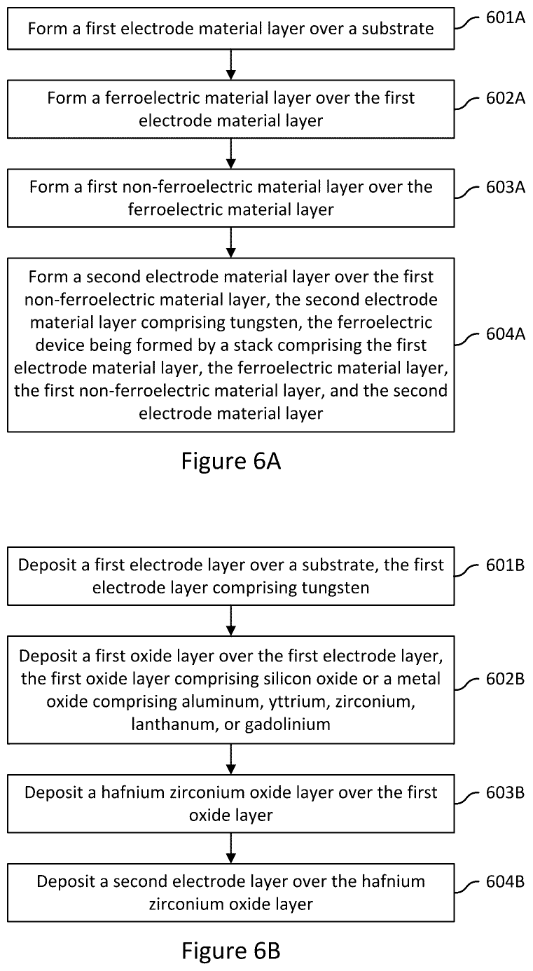

The process flows described with reference to FIGS. 3A-3E and (jointly) FIGS. 4A-4E and 5A-5E may represent various embodiments of a more general method of forming a ferroelectric device, as illustrated by a flow chart in FIG. 6A.

In box 601A, a first electrode material layer is formed over a substrate. Next, in box 602A, a ferroelectric material layer is formed over the first electrode material layer. Then, in box 603A, a first non-ferroelectric material layer is formed over the ferroelectric material layer. In some embodiments further comprising formation of a second non-ferroelectric material layer between the first electrode material layer and the ferroelectric material layer, these steps may result in a structure like that illustrated in FIG. 3A. Some embodiments may further comprise annealing the ferroelectric material layer before proceeding to box 604, resulting in structures like those illustrated in FIG. 3B or in FIGS. 4A and 5A.

With further reference to FIG. 6A and the method charted therein, in box 604A, a second electrode material layer comprising tungsten is formed over the first non-ferroelectric material layer. The ferroelectric device is formed by a stack comprising the first electrode material layer, the ferroelectric material layer, the first non-ferroelectric material layer, and the second electrode material layer.

In some embodiments further comprising a patterning and etching of the stack, the method presented in FIG. 6A may result in a ferroelectric device like that in FIG. 1B. Embodiments further comprising patterning and etching of the stack without annealing of the ferroelectric material layer are not illustrated but may be suitable, for example, when the ferroelectric material layer comprises as initially formed a sufficient remanent polarization for a given device design.

In other embodiments further comprising formation of a second non-ferroelectric material layer between the first electrode material layer and the ferroelectric material layer before patterning and etching of the stack, the method may result in a ferroelectric device like that illustrated in FIGS. 1A/3D or FIGS. 4D and 5D. In such embodiments also further comprising formation of a contact via to the ferroelectric device, these steps may result in an integrated ferroelectric device like that illustrated in FIG. 3E or in FIGS. 4E and 5E.

The process flows described with reference to FIGS. 3A-3E and (jointly) FIGS. 4A-4E and 5A-5E may also represent various embodiments of another method of forming a ferroelectric device, as illustrated by a flow chart in FIG. 6B.

In box 601B, a first electrode layer comprising tungsten is deposited over a substrate. Next, in box 602B, a first oxide layer comprising aluminum, yttrium, zirconium, lanthanum, or gadolinium is deposited over the first electrode layer. Then, in box 603A, a hafnium zirconium oxide layer is deposited over the first oxide layer. In some embodiments further comprising formation of a second oxide layer between the hafnium zirconium oxide layer and a second electrode layer (to be deposited per box 604B), these steps may result in a structure like that illustrated in FIG. 3A. Some embodiments may further comprise annealing the hafnium zirconium oxide layer before proceeding to box 604B, resulting in structures like those illustrated in FIG. 3B or in FIGS. 4A and 5A.

In box 604B, a second electrode layer is deposited over the hafnium zirconium oxide layer. In some embodiments further comprising a patterning and etching of the stack, the method presented in FIG. 6B may result in a ferroelectric device like that in FIG. 1C. Embodiments further comprising patterning and etching of the stack without annealing of the ferroelectric material layer are not illustrated but may be suitable, for example, when the ferroelectric material layer comprises as initially formed a sufficient remanent polarization for a given device design.

In other embodiments further comprising formation of a second oxide layer between the hafnium zirconium oxide layer and the second electrode before patterning and etching of the stack, these steps may result in a ferroelectric device like that illustrated in FIGS. 1A/3D or FIGS. 4D and 5D. In such embodiments also further comprising formation of a contact via to the ferroelectric device, these steps may result in an integrated ferroelectric device like that illustrated in FIG. 3E or in FIGS. 4E and 5E.

Devices integrating the ferroelectric devices of FIG. 3E or FIGS. 4E and 5E may comprise, according to various embodiments, FTJs, FeRAM, FeFETs, negative-capacitance field-effect transistors (NCFETs), ferroelectric content-addressable memories (FeCAMs) such as ferroelectric ternary CAMs (FeTCAMs), artificial synapses for physical neural networks or neuromorphic computing (such as reservoir computing), and other such devices.

Example embodiments of the invention are described below. Other embodiments can also be understood from the entirety of the specification as well as the claims filed herein.

Example 1. A method of forming a ferroelectric device, the method including: forming a first electrode material layer over a substrate; forming a ferroelectric material layer over the first electrode material layer; forming a first non-ferroelectric material layer over the ferroelectric material layer; and forming a second electrode material layer over the first non-ferroelectric material layer, the second electrode material layer including tungsten, the ferroelectric device being formed by a stack including the first electrode material layer, the ferroelectric material layer, the first non-ferroelectric material layer, and the second electrode material layer.

Example 2. The method of example 1, where the first non-ferroelectric material layer includes a thickness between 0.3 nm and 5 nm.

Example 3. The method of one of examples 1 or 2, where the ferroelectric material layer includes hafnium zirconium oxide, lithium niobate, barium titanate, aluminum scandium nitride, zinc magnesium oxide, or indium (III) selenide.

Example 4. The method of one of examples 1 to 3, where the first non-ferroelectric material layer covers the ferroelectric material layer during formation of the second electrode material layer.

Example 5. The method of one of examples 1 to 4, where the first non-ferroelectric material layer is resistant to etching during formation of the second electrode material layer.

Example 6. The method of one of examples 1 to 5, where the first non-ferroelectric material layer includes silicon oxide or a metal oxide.

Example 7. The method of one of examples 1 to 6, where the metal oxide includes aluminum, yttrium, zirconium, lanthanum, or gadolinium.

Example 8. The method of one of examples 1 to 7, where the first non-ferroelectric material layer includes titanium nitride or tantalum nitride.

Example 9. The method of one of examples 1 to 8, where the first non-ferroelectric material layer includes a metal liner, the metal liner including aluminum, titanium, zirconium, hafnium, or tantalum.

Example 10. The method of one of examples 1 to 9, where the first electrode material layer includes an elemental semiconductor material, a compound semiconductor material, an oxide semiconductor material, or a 2D semiconductor material.

Example 11. The method of one of examples 1 to 10, where the first electrode material layer includes scandium, cobalt, nickel, zirconium, molybdenum, ruthenium, rhodium, hafnium, tungsten, or rhenium.

Example 12. The method of one of examples 1 to 11, where the second electrode material layer is deposited using a metal halide precursor.

Example 13. The method of one of examples 1 to 12, where the second electrode material layer is deposited using a non-halide precursor, and where the non-halide precursor includes a carbonyl precursor or a metal-organic precursor.

Example 14. The method of one of examples 1 to 13, where the second electrode material layer is deposited using a tungsten halide precursor, a tungsten carbonyl precursor, a tungsten metal-organic precursor, or a combination of thereof.

Example 15. The method of one of examples 1 to 14, further including annealing the ferroelectric material layer.

Example 16. The method of one of examples 1 to 15, further including forming a second non-ferroelectric material layer between the first electrode material layer and the ferroelectric material layer.

Example 17. The method of one of examples 1 to 16, where the first electrode material layer, the ferroelectric material layer, the first non-ferroelectric material layer, and the second electrode material layer are deposited in one or more processing chambers without air exposure between forming of the first electrode material layer, forming of the ferroelectric material layer, forming of the first non-ferroelectric material layer, and forming of the second electrode material layer.

Example 18. A method of forming a ferroelectric device, the method including: depositing a first electrode layer over a substrate, the first electrode layer including tungsten; depositing a first oxide layer over the first electrode layer, the first oxide layer including silicon oxide or a metal oxide including aluminum, yttrium, zirconium, lanthanum, or gadolinium; depositing a hafnium zirconium oxide layer over the first oxide layer; and depositing a second electrode layer over the hafnium zirconium oxide layer.

Example 19. The method of example 18, where the second electrode layer includes scandium, cobalt, nickel, zirconium, molybdenum, ruthenium, rhodium, hafnium, tungsten, or rhenium.

Example 20. The method of one of examples 18 or 19, further including annealing the hafnium zirconium oxide layer.

Example 21. The method of one of examples 18 to 20, further including forming a second oxide layer between the hafnium zirconium oxide layer and the second electrode layer.

Example 22. The method of one of examples 18 to 21, where a thickness of the first oxide layer is between 0.3 nm and 5 nm.

Example 23. A ferroelectric device including: a first electrode disposed over a substrate; a second electrode disposed over the first electrode, the second electrode including tungsten; and a dielectric stack disposed between the first electrode and the second electrode, the dielectric stack including a first oxide layer, a second oxide layer, and a ferroelectric material layer disposed between the first oxide layer and the second oxide layer.

Example 24. The ferroelectric device of example 23, where the ferroelectric material layer includes hafnium zirconium oxide, lithium niobate, barium titanate, aluminum scandium nitride, zinc magnesium oxide, or indium (III) selenide.

Example 25. The ferroelectric device of one of examples 23 or 24, where each of the first oxide layer and the second oxide layer includes silicon oxide or a metal oxide.

Example 26. The ferroelectric device of one of examples 23 to 25, where the metal oxide includes aluminum, yttrium, zirconium, lanthanum, or gadolinium.

Example 27. The ferroelectric device of one of examples 23 to 26, where a thickness of each of the first oxide layer and the second oxide layer is between 0.3 nm and 5 nm.

While this invention has been described with reference to illustrative embodiments, this description is not intended to be construed in a limiting sense. Various modifications and combinations of the illustrative embodiments, e.g., of FIG. 1 and FIGS. 3-6, as well as other embodiments of the invention, will be apparent to persons skilled in the art upon reference to the description. It is therefore intended that the appended claims encompass any such modifications or embodiments.

What is claimed is:

1. A method of forming a ferroelectric device, the method comprising:
forming a first electrode material layer over a substrate;
forming a ferroelectric material layer over the first electrode material layer;
forming a first non-ferroelectric material layer over the ferroelectric material layer; and
forming a second electrode material layer over the first non-ferroelectric material layer, the second electrode material layer comprising tungsten, the ferroelectric device being formed by a stack comprising the first electrode material layer, the ferroelectric material layer, the first non-ferroelectric material layer, and the second electrode material layer.

2. The method of claim 1, wherein the first non-ferroelectric material layer comprises a thickness between 0.3 nm and 5 nm.

3. The method of claim 1, wherein the ferroelectric material layer comprises hafnium zirconium oxide, lithium niobate, barium titanate, aluminum scandium nitride, zinc magnesium oxide, or indium (III) selenide.

4. The method of claim 1, wherein the first non-ferroelectric material layer is resistant to etching during formation of the second electrode material layer.

5. The method of claim 1, wherein the first non-ferroelectric material layer comprises silicon oxide or a metal oxide.

6. The method of claim 5, wherein the metal oxide comprises aluminum, yttrium, zirconium, lanthanum, or gadolinium.

7. The method of claim 1, wherein the first non-ferroelectric material layer comprises titanium nitride, tantalum nitride, or a metal liner, the metal liner comprising aluminum, titanium, zirconium, hafnium, or tantalum.

8. The method of claim 1, wherein the first electrode material layer comprises an elemental semiconductor material, a compound semiconductor material, an oxide semiconductor material, or a 2D semiconductor material.

9. The method of claim 1, wherein the first electrode material layer comprises scandium, cobalt, nickel, zirconium, molybdenum, ruthenium, rhodium, hafnium, tungsten, or rhenium.

10. The method of claim 1, wherein the second electrode material layer is deposited using a metal halide precursor.

11. The method of claim 1, further comprising annealing the ferroelectric material layer.

12. The method of claim 1, further comprising forming a second non-ferroelectric material layer between the first electrode material layer and the ferroelectric material layer.

13. A method of forming a ferroelectric device, the method comprising:
depositing a first electrode layer over a substrate, the first electrode layer comprising tungsten;
depositing a first oxide layer over the first electrode layer, the first oxide layer comprising silicon oxide or a metal oxide comprising aluminum, yttrium, zirconium, lanthanum, or gadolinium;
depositing a hafnium zirconium oxide layer over the first oxide layer; and
depositing a second electrode layer over the hafnium zirconium oxide layer.

14. The method of claim 13, wherein the second electrode layer comprises scandium, cobalt, nickel, zirconium, molybdenum, ruthenium, rhodium, hafnium, tungsten, or rhenium.

15. The method of claim 13, further comprising forming a second oxide layer between the hafnium zirconium oxide layer and the second electrode layer.

16. The method of claim 13, wherein a thickness of the first oxide layer is between 0.3 nm and 5 nm.

17. A ferroelectric device comprising:
a first electrode disposed over a substrate;
a second electrode disposed over the first electrode, the second electrode comprising tungsten; and
a dielectric stack disposed between the first electrode and the second electrode, the dielectric stack comprising a first oxide layer, a second oxide layer, and a ferroelectric material layer disposed between the first oxide layer and the second oxide layer.

18. The ferroelectric device of claim 17, wherein the ferroelectric material layer comprises hafnium zirconium oxide, lithium niobate, barium titanate, aluminum scandium nitride, zinc magnesium oxide, or indium (III) selenide.

19. The ferroelectric device of claim 17, wherein each of the first oxide layer and the second oxide layer comprises silicon oxide or a metal oxide, the metal oxide comprising aluminum, yttrium, zirconium, lanthanum, or gadolinium.

20. The ferroelectric device of claim 17, wherein a thickness of each of the first oxide layer and the second oxide layer is between 0.3 nm and 5 nm.
